(19) United States
(12) Patent Application Publication
(10) Pub. No.: US 2010/0289283 A1
(43) Pub. Date: Nov. 18, 2010

(54) Chip Pickup Method and Chip Pickup Apparatus

(75) Inventors: Kenichi Watanabe, Tokyo (JP); Takeshi Segawa, Tokyo (JP); Hironobu Fujimoto, Tokyo (JP)

Correspondence Address: THE WEBB LAW FIRM, P.C., 700 KOPPERS BUILDING, 436 SEVENTH AVENUE, PITTSBURGH, PA, 15219, US

(73) Assignee: LINTEC CORPORATION, Tokyo (JP)

(21) Appl. No.: 12/445,689

(22) PCT Filed: Oct. 12, 2007
(86) PCT No.: PCT/JP2007/070009

§ 371 Date: Apr. 15, 2009

(30) Foreign Application Priority Data
Oct. 18, 2006 (JP) 2006-283983

(51) Int. Cl. B25J 15/06; H01L 21/683

(52) U.S. Cl. 294/64.1; 257/E21.001

(57) ABSTRACT

A method is provided for picking up a chip 13 from a fixing jig 3 to which the chip 13 is fixed. The fixing jig 3 consists of a jig base 30 having a plurality of protrusions 36 on one side and a sidewall 35 having a height almost equivalent to that of the protrusion 36 at the outer circumference of the one side, and an contact layer 31 that is laminated on the surface of the jig base 30 having the protrusions 36 and that is bonded on the upper surface of the sidewall 35. A section space 37 is formed on the surface of the jig base 30 having the protrusions by the contact layer 31, the protrusions 36 and the sidewall 35, and at least one through hole 38 penetrating the outside and the section space 37 is provided in the jig base 30. The pickup method comprises the steps of fixing a chip, deforming the contact layer 31 by suctioning of air in the section space 37 through the through hole 38, and picking up the chip 13 completely from the contact layer 31 by suctioning the chip 13 from the upper surface side of the chip 13 by means of a suction collet 70.

### TECHNICAL FIELD

The present invention relates to a pickup method and a pickup apparatus in which the pushing up of a chip is not carried out. More specifically, the present invention relates to a chip pickup method and a chip pickup apparatus in which a comparatively large-area semiconductor chip that has been ground to be extremely thin can be picked up without damage.

### BACKGROUND ART

In recent years, an IC card and a mobile electronic device has been become popular and much further thinning of a semiconductor component has been desired. Consequently, a conventional semiconductor chip having a thickness of approximately 350 μm has to be further thinner to be in the range of 50 to 100 μm or less.

To form a semiconductor chip, after a front surface circuit formation is carried out, a predetermined thickness of the semiconductor chip is ground from the rear face, and a dicing is carried out for every circuit. As another method, after a front surface circuit formation is carried out, a groove having a depth more than a predetermined depth from the circuit surface is formed, and the rear face is ground in such a manner that a semiconductor chip has a predetermined thickness (dicing before grinding method) to form a semiconductor chip.

A semiconductor chip that has been fixed on a pressure sensitive adhesive sheet such as a dicing sheet to prevent chips from being separated is brought to a pickup process. In the case in which a chip on the pressure sensitive adhesive sheet is picked up, the pressure sensitive adhesive sheet under the rear face of the chip is pushed up by means of a fine needle to reduce an area of contact with the pressure sensitive adhesive sheet. The chip that has been pushed up by a fine needle is sucked by means of a suction collet from the upper surface side of the chip, and is detached from the pressure sensitive adhesive sheet. The chip is then transferred to a die pad of a chip substrate or the like.

Since a chip has been thinned, the pushing up of a chip by means of a fine needle delivers a considerable damage to the chip. A semiconductor device in which a chip that has been damaged is used possesses lower reliability, for instance, a package crack occurs by receiving a heat history. In addition, in the case in which a suffered damage is serious, a chip may be broken due to the pushing up of the chip in some cases.

To solve such problems, a pickup method in which the pushing up of a chip by means of a fine needle is not carried out is studied (Japanese Patent Application Laid-Open Publication No. 2003-179126 (see Patent document 1)). In the pickup method, a suction table of a porous material is used in place of a pressure sensitive adhesive tape, and a suction of a suction table is stopped to cancel the holding force of a chip in the case in which a chip is picked up. However, in this method, a gap between chips cannot be sealed and an air leaks. Moreover, a leak amount increases as a chip is picked up. By this, a holding force to a remaining chip that is not picked up is reduced, and a location of a chip is out of alignment by a vibration, whereby a collet cannot catch a chip.

Patent document 1: Japanese Patent Application Laid-Open Publication No. 2003-179126

### DISCLOSURE OF THE INVENTION

### Problems to be Solved by the Invention

The present invention was made in consideration of the above problems, and an object of the present invention is to provide a pickup method wherein the pushing up of a chip is not required and a force for holding a chip that is not picked up is not varied as a pickup is progressed and a pickup apparatus suitable for achieving the pickup method.

### Means for Solving the Problems

A chip pickup method in accordance with the present invention is characterized by a method for picking up a chip from a fixing jig to which the chip is fixed,

the fixing jig comprising a jig base provided with a plurality of protrusions on one side thereof and a sidewall having a height almost equivalent to that of the protrusion at the outer circumference section of the one side, and an contact layer that is laminated on the surface of the jig base having the protrusions and that is bonded on the upper surface of the sidewall,

the jig base comprising a section space that is formed on the surface of the jig base having the protrusions by the contact layer, the protrusions, and the sidewall, and at least one through hole penetrating from the outside to the section space,

wherein the chip pickup method comprising of:

a chip fixing step for fixing a chip in a state in which the chip is fixed to the surface of the contact layer of the fixing jig;
a contact layer deforming step for deforming the contact layer by suctioning an air in the section space through the through hole; and
a pickup step for picking up the chip completely from the contact layer by suctioning the chip from the upper surface side of the chip by means of a suction collet.

The present invention can be preferably applied to a semiconductor chip that is obtained by segmenting a semiconductor wafer into chip pieces.

According to a preferred embodiment of the chip pickup method of the present invention,

the semiconductor chips are obtained by segmenting a semiconductor chip into chip pieces through dicing on a dicing sheet, and

the semiconductor chips are arranged on the surface of the contact layer of the fixing jig by contacting an exposed face of the semiconductor chips to the contact layer of the fixing jig, and removing the dicing sheet.

According to a preferred embodiment of the chip pickup method of the present invention,

the semiconductor chips are obtained by half-cutting a circuit face of the semiconductor wafer, protecting the circuit face with a protection sheet, and grinding the rear face of the semiconductor wafer up to a half-cut groove whereby the semiconductor wafer is segmented into chip pieces, and

the semiconductor chips are arranged on the surface of the contact layer of the fixing jig by contacting an exposed face of the semiconductor chips to the contact layer of the fixing jig, and removing the protection sheet.

According to a preferred embodiment of the chip pickup method of the present invention,

a semiconductor wafer is irradiated with a laser beam to form a brittle part in the semiconductor wafer;

the position of the laser beam incident on the wafer surface is moved to create the brittle parts in a desired outline; and
a shock is applied to the semiconductor wafer to break the brittle parts and thereby the wafer is segmented into pieces; and

the semiconductor wafer is contacted to the contact layer of the fixing jig before irradiated with the laser beam.

A chip pickup apparatus in accordance with the present invention is characterized by a chip pickup apparatus that is used in the pickup method in accordance with the present invention, and comprising:

a table for fixing the fixing jig; and
a suction collet for suctioning and holding the chip,

wherein the table is provided with a suction part for fixing the fixing jig body, and a suction part for suctioning the section space connected to a through hole of the fixing jig, in which the suction parts are opened and capable of suctioning independently.

For the chip pickup apparatus having the above configuration in accordance with the present invention, the suction is carried out via a through hole from the fixing jig to which the chip contacts whereby the section space is depressurized. At a section apart from the protrusion and between chips, the contact layer is drawn to the bottom part of the jig base by the depressurization. An ambient air then flows between the chip and the surface of the contact layer from the periphery of the chip to cause the chip to be detached from the contact layer. Consequently, only the upper face on the protrusion contacts to the chip. Therefore, the chip is fixed to the fixing jig with an extremely small contact force, thereby the chip can be picked up by only the suction of the suction collet.

Even in the case in which chips are picked up by the suction collet continuously, a contact state with a chip that remains on the fixing jig does not vary due to a leak of an air. Consequently, each chip can be fixed to the fixing jig with a stable small contact force at any time, therefore preventing each chip from being displaced.

By the apparatus in accordance with the present invention, the pickup method in accordance with the present invention can be easily carried out.

The chip pickup apparatus in accordance with the present invention is preferably characterized in that the table can move in an X direction, a Y direction, and a rotating direction, and can control the position in such a manner that a targeted chip and the suction collet can be aligned with each other.

By the above configuration, any chip that has been disposed on the prescribed position can be freely picked up selectively.

### Effect of the Invention

By the chip pickup method and the chip pickup apparatus in accordance with the present invention, the chip can be picked up by only the suction force of the suction collet without the pushing up of the rear face of the chip using a fine needle. Consequently, the chip is not damaged.

Moreover, even in the case in which chips are picked up continuously, a contact state with a chip that remains on the fixing jig does not vary. Consequently, an operation for adjusting a suction force for preventing a displacement of a chip is not required in the later step of the pickup.

Consequently, even for a chip that has been processed to be extremely thin, the chip can be picked up and safely transferred to the next step.

Moreover, by the chip pickup method and the chip pickup apparatus in accordance with the present invention, the contact layer is deformed ununiformly in a concave-convex shape by suctioning an air in the section space through the through hole from the state in which the chip is fixed to the surface of the contact layer of the fixing jig. By this, the chip that has been fixed to the contact layer by a face contact is changed to a chip in a spot contact state, thereby simplifying the chip to be detached. Consequently, in the case in which the suction collet suctions the upper side of the chip, the chip can be easily picked up without the pushing up of the rear face of the chip using a fine needle. Moreover, even in the case in which the suction collet picks up chips continuously, a contact state with a chip that remains on the fixing jig does not vary due to a leak of an air. Consequently, each chip can be fixed to the fixing jig with a stable small contact force at any time, and therefore the chips can be picked up without displacement until the last chip is picked up.

### BRIEF DESCRIPTION OF THE DRAWINGS

FIG. 1 is a schematic cross-sectional view showing a fixing jig that is used in a pickup apparatus for carrying out a pickup method in accordance with the present invention.

FIG. 2 is a schematic plan view showing a jig base that configures a fixing jig in the fixing jig shown in FIG. 1.

FIG. 3 is a schematic plan view showing a semiconductor wafer in which chip pieces are segmented and processed by the pickup apparatus in accordance with the present invention.

FIG. 4 is a schematic cross-sectional view showing a state in which the semiconductor wafer that has been segmented into chip pieces is disposed on a fixing apparatus.

FIG. 5 is a schematic cross-sectional view showing an operation in which an air is introduced from the fixing apparatus shown in FIG. 4, in particular, a chip fixing step.

FIG. 6 is a schematic elevational view showing the pickup apparatus suitable for carrying out a pickup method in accordance with the present invention.

### EXPLANATIONS OF LETTERS OR NUMERALS

1: Semiconductor wafer
3: Fixing jig
4: Vacuum apparatus
13: Chip
30: Jig base
31: Contact layer
35: Sidewall
36: Protrusion
37: Section space
38: Through hole
50: Suction part
51: Table
52: Suction part
70: Suction collet
70a: Suction part
100: Pickup apparatus

### BEST MODE OF CARRYING OUT THE INVENTION

An embodiment of the present invention will be described below in detail with reference to the drawings.

### <Fixing Jig>

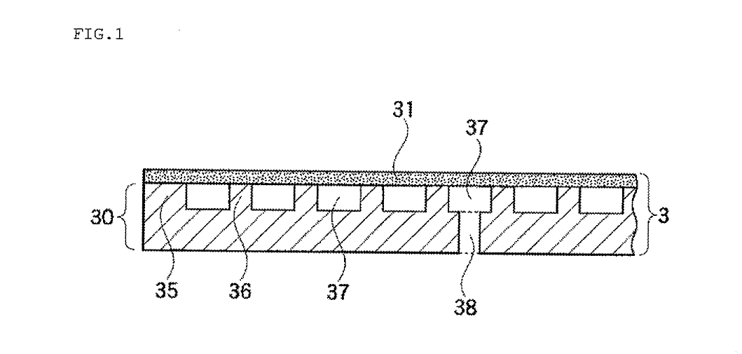

At first, a fixing jig that is used for the present invention will be described below. The fixing jig shown in FIG. 1 is built in the pickup apparatus in accordance with the present invention to be used.

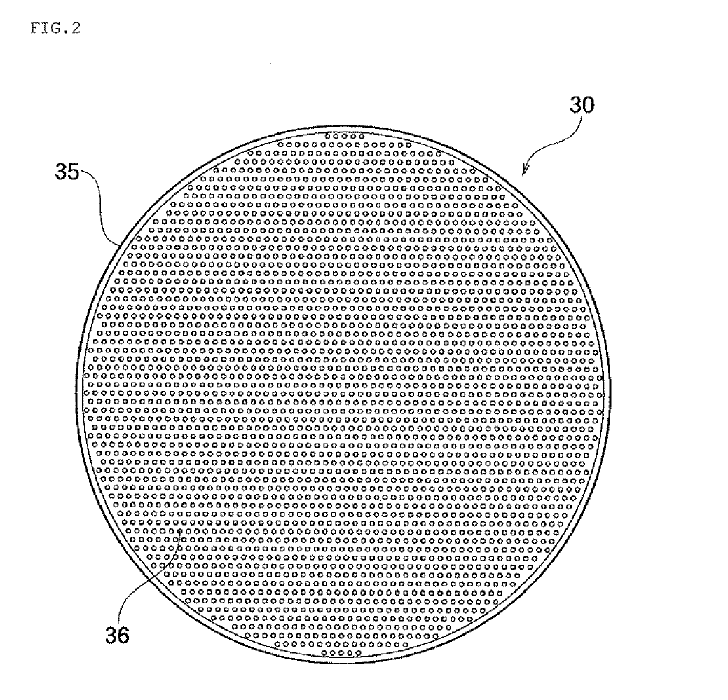

As shown in FIG. 1, a fixing jig 3 that is used for the present invention is composed of a jig base 30 and an contact layer 31. As a shape of the jig base 30, there can be mentioned for instance an approximately circular shape, an approximately elliptical shape, an approximately rectangular shape, and an approximately polygonal shape, and an approximately circular shape is preferable. As shown in FIGS. 1 and 2, a plurality of protrusions 36 is formed on one face of the jig base 30 in such a manner that the protrusions 36 space out from each other and protrude upward. A shape of the protrusions 36 is not restricted in particular. However, a cylindrical shape or a circular truncated cone shape is preferable. A sidewall 35 having a height almost equivalent to that of the protrusion 36 is formed on the outer circumference section of the face on which the protrusions 36 are formed. In addition, the contact layer 31 is laminated on the face on which the protrusions are formed. The contact layer 31 is bonded to the upper face of the sidewall 35. The contact layer 31 and the upper face of the protrusions 36 can be bonded to each other. Alternatively, the contact layer 31 and the upper face of the protrusions 36 are not bonded to each other. The section spaces 37 are formed by the protrusions 36, the sidewall 35, and the contact layer 31 on the face provided with the protrusions for the jig base 30. The section spaces 37 are communicated with each other.

On the other hand, on the face on which the protrusions are not formed for the jig base 30, a through hole 38 that penetrates between the outside on this face side and the section space 37 is formed in a direction of a thickness of the jig base 30. At least one through hole 38 is formed in the jig base 30. A plurality of through holes can also be formed. In place of the through hole 38 on the face on which the protrusions are not formed for the jig base 30, a through hole 38 can also be formed in a horizontal direction of the jig base 30, and an opening part can be formed on the sidewall 35. By connecting a vacuum apparatus detachably to the opening part of the through hole 38, a gas in the section space 37 is exhausted, and the contact layer 31 can be deformed in a concave-convex shape.

The material of the jig base 30 is not restricted in particular in the case in which the jig base 30 has a large mechanical strength. As the material of the jig base 30, there can be mentioned for instance a thermoplastic resin such as polycarbonate, polypropylene, polyethylene, a polyethylene terephthalate resin, an acrylic resin, and polyvinyl chloride, and a metallic material such as an aluminum alloy, a magnesium alloy, and stainless steel, and an inorganic material such as glass, and an organic/inorganic composite material such as a glass fiber reinforced epoxy resin. It is preferable that a modulus of elasticity in bending for the jig base 30 is at least 1 GPa. In the case in which the jig base 30 has such modulus of elasticity in bending, the jig base 30 can have stiffness even if a thickness of the jig base is not more than necessary. By using such material, the jig base is not bent in a transfer from a contact of a chip to the fixing jig to mounting of the chip on the pickup apparatus, thereby preventing a displacement and a dropout of a chip.

It is preferable that an outside diameter of the jig base 30 is almost equivalent to or larger than that of a semiconductor wafer. In the case in which the jig base 30 has an outside diameter that can correspond to the maximum diameter of a standardized size of a semiconductor wafer (for instance 300 mm diameter), the jig base 30 can be applied to all of semiconductor wafers having a diameter smaller than the maximum diameter of a standardized size. Moreover, it is preferable that a thickness of the jig base 30 is in the range of 0.5 to 2.0 mm, more preferably in the range of 0.5 to 0.8 mm. In the case in which a thickness of the jig base is in the above range, a wafer can be adequately held without bending the wafer after grinding the rear face of the wafer.

It is preferable that a height of the protrusion 36 and the sidewall 35 is in the range of 0.05 to 0.5 mm. Moreover, it is preferable that a diameter of the upper face of the protrusion 36 is in the range of 0.05 to 1.0 mm. Moreover, it is preferable that an interval between the protrusions (a center-to-center distance of the protrusions) is in the range of 0.2 to 2.0 mm. In the case in which a size of the protrusion 36 and an interval between the protrusions are in the above ranges, the contact layer 31 can be deformed sufficiently in a concave-convex shape due to a deaeration in the section space 37, and a semiconductor chip can be easily detached from the contact layer 31. Moreover, the contact layer 31 can be restored to an original flat state even after a concavoconvex deformation of the contact layer 31 is repeated many times.

A diameter of the through hole 38 is not restricted in particular. However, it is preferable that a diameter of the through hole 38 is 2 mm or less.

For the jig base 30, the bottom part, the sidewall 35, and the protrusion 36 of the jig base can be produced, for instance, in an integrated manner by heat molding of materials made of thermoplastic resin using a mold. Alternatively, the jig base 30 can be produced by forming the sidewall 35 and the protrusion 36 on a flat circular plate. Alternatively, the jig base 30 can be produced by forming the protrusion 36 on the surface in a concave portion of a depressed circular plate. As a forming method of the protrusion 36, there can be mentioned for instance a method for depositing metal in a prescribed shape by electroforming, a method for forming a protrusion by screen printing, and a method for laminating a photoresist on a flat circular plate and for forming a protrusion by an exposure and a development. Moreover, the jig base 30 can also be produced by a method for eroding and removing the surface of a metallic flat circular plate by etching while leaving a protrusion formation part and a method for removing the surface of a flat circular plate by sand blasting while leaving a protrusion formation part. The through hole 38 can be formed in advance before forming a protrusion. Alternatively, the through hole 38 can be formed after forming a protrusion. Alternatively, the through hole 38 can be formed at the same time when the jig base is molded.

As a material of the contact layer 31 disposed on the jig base 30, there can be mentioned for instance an elastomer of urethane series, acrylic series, fluororesin series, or silicone series, which is excellent for pliability, flexibility, heat resisting properties, elasticity, and adherence properties. The addition agents of various kinds such as a reinforcing filler and hydrophobic silica can be added to the elastomer as needed.

It is preferable that the contact layer 31 is a flat plate in a shape almost equivalent to that of the jig base 30. It is preferable that an outside diameter of the contact layer 31 is almost equivalent to that of the jig base 30. It is preferable that a thickness of the contact layer 31 is in the range of 20 to 200 μm. In the case in which a thickness of the contact layer 31 is less than 20 μm, a mechanical durability to repeated suctions becomes less in some cases. On the other hand, in the case in which a thickness of the contact layer 31 exceeds 200 μm, it takes a long time for a detachment caused by suction disadvantageously.

It is preferable that the tensile break strength of the contact layer 31 is at least 5 MPa and a breaking elongation of the contact layer 31 is at least 500%. In the case in which the tensile break strength and a breaking elongation are in the above ranges, the contact layer 31 is not broken and not loosened, and the contact layer 31 can be restored to an original flat state even if a deformation of the contact layer 31 is repeated many times.

It is preferable that a modulus of elasticity in bending for the contact layer 31 is in the range of 10 to 100 MPa. In the case in which a modulus of elasticity in bending for the contact layer 31 is less than 10 MPa, a part other than a contact point of the contact layer 31 with the protrusion 36 undergoes a bend due to gravity, whereby the contact layer 31 cannot contact to a chip in some cases. On the other hand, in the case in which a modulus of elasticity in bending for the contact layer 31 exceeds 100 MPa, a deformation caused by suction is hard to occur, and a chip cannot be easily detached in some cases.

It is preferable that a shearing force for contact to a face on the side that comes into attaching to a semiconductor wafer for the contact layer 31 is at least 35 N. In the present invention, a shearing force is a value that is measured between the contact layer 31 and a mirror face of a silicon wafer. The contact layer 31 is bonded to a well-known glass plate having a size of 30 mm long, 30 mm wide, and 3 mm thick, and the glass plate is disposed on a mirror wafer composed of silicon. In the case in which a load of 900 g is applied to the entire of a glass plate and the contact layer 31 for 5 seconds and the glass plate is pressed while applying a load in parallel to the mirror wafer, a load is measured when the glass plate starts to move.

Moreover, it is preferable that a contact force of the contact layer 31 is 2N/25 mm or less. In the case in which a contact force of the contact layer 31 exceeds 2N/25 mm, a contact between the contact layer 31 and a chip disposed on the contact layer is too strong, thereby causing a blocking state. Consequently, a detachment of a chip due to suction may be impossible. A contact force in accordance with the present invention is detachment strength in the case in which the contact layer 31 is mounted to a mirror face of a wafer and is detached.

The contact layer 31 can be formed by fabricating a film made of the above elastomer in advance based on a process such as a calendar method, a pressing method, a coating method, and a printing method, and by bonding the elastomer film on the upper face of at least the sidewall 35 of the jig base 30. By this, the section space 37 is formed. As a method for bonding the contact layer 31, there can be mentioned for instance a method for bonding the contact layer 31 through an adhesive made of a resin such as an acrylic resin, a polyester resin, an epoxy resin, a silicone resin, and an elastomer resin, and a method for bonding the contact layer 31 through a manner by heat sealing in the case in which the contact layer 31 has heat sealing characteristics.

An un-sticking treating can be applied to the surface of the contact layer 31. In particular, it is preferable that an un-sticking treating is applied to only the surface of the contact layer upper the protrusions 36 that comes into contact with a semiconductor chip in the case in which the contact layer 31 is deformed in a concave-convex shape. By this treating, a surface part to which an un-sticking treating is not applied for the contact layer contacts to a semiconductor chip before the contact layer 31 is deformed, and only the surface over the protrusions 36, that is, an un-sticking convex surface comes into contact with a semiconductor chip in the case in which the contact layer 31 is deformed in a concave-convex shape. Consequently, a semiconductor chip can be further easily detached from the contact layer 31. As a method of an un-sticking treating, there can be mentioned for instance a method for deforming the contact layer 31 in a concave-convex shape by suctioning an air in the section space 37 using a vacuum apparatus and for physically roughening the end of the convex part using a grind stone roller or the like, an ultraviolet treatment method, a method for laminating a non-adhesive rubber, and a method for coating a non-adhesive paint. For a surface roughness of a treating part, an arithmetic mean roughness Ra is preferably at least 1.6 μm, more preferably in the range of 1.6 to 12.5 μm. In the case in which a treating part is roughened based on a surface roughness in the above range, the contact layer 31 is not deteriorated, and a semiconductor chip can be easily detached from the contact layer 31.

### <Chip>

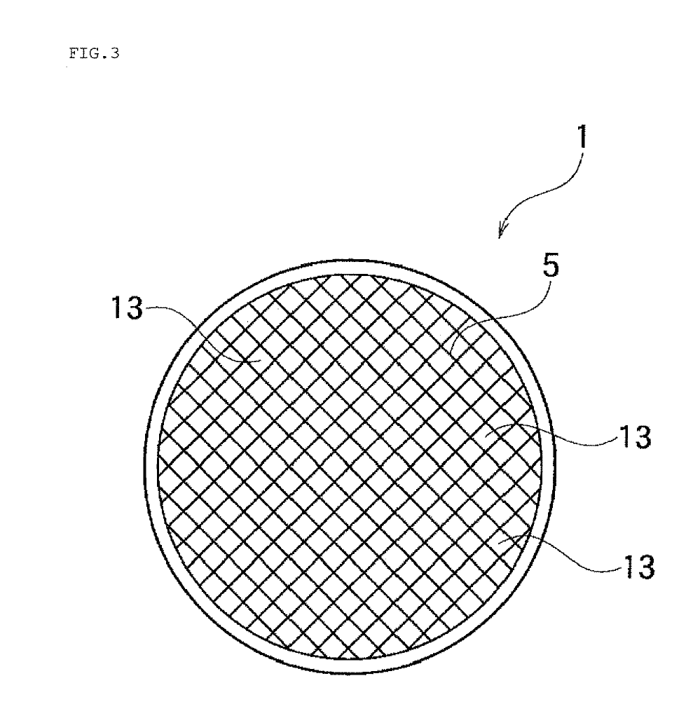

As shown in FIG. 3, a processed body that is picked up in the present invention is a semiconductor wafer 1 that has been diced by a cutting line 5 through a dicing process. By the above process, the semiconductor wafer 1 is segmented into a plurality of chips 13 in advance.

A circuit is formed on a silicon semiconductor wafer or a gallium arsenide semiconductor wafer, and so on, and chip pieces are segmented from the wafer to obtain the chip 13. In this embodiment, a semiconductor chip formed by segmenting a semiconductor wafer into chip pieces is the chip 13. However, the chip 13 is not restricted to the above embodiment. Chips of many kinds that are segmented from a flat plate such as an organic substrate, a ceramic substrate, and a glass substrate can also be used. A circuit can be formed on a wafer surface by various methods such as an etching process and a liftoff process.

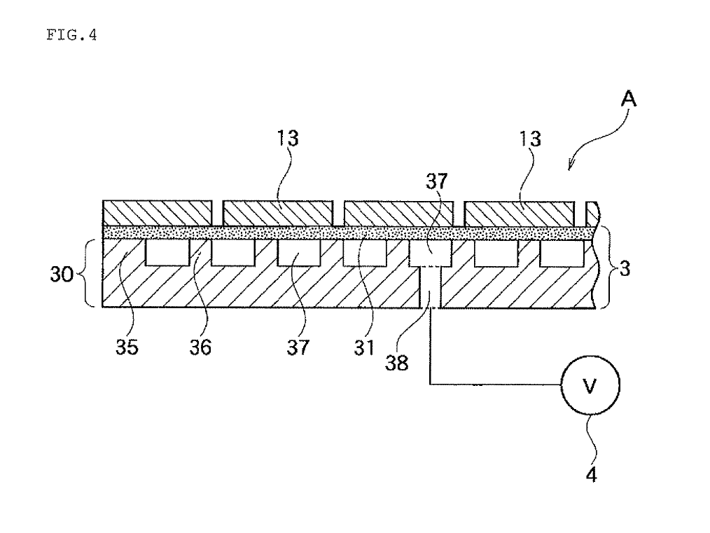

As shown in FIG. 4, the semiconductor wafer 1 in which a plurality of chips 13 is separated is then disposed on the fixing jig 3.

A means for achieving the state in which the semiconductor wafer 1 in which a great number of chips 13 is separated is mounted on the contact layer 31 of the fixing jig 3 is not restricted in particular. Providing the state shown in FIG. 4 can be achieved as a result, any steps can be processed.

For instance, the semiconductor wafer can be diced using a normal dicing sheet, and can be transferred to the contact layer 31. Therefore, chips 13 can maintain a wafer shape on the contact layer 31. Moreover, the contact layer 31 can be used as a dicing sheet, and only the semiconductor wafer 1 can be diced without cutting the contact layer 31. Furthermore, in place of a dicing apparatus provided with a dicing blade, a dicing apparatus based on laser beams (laser dicer) can also be used. For the laser dicer, a focal point of laser beams is controlled to divide a wafer, thereby enabling easy control not to cut the contact layer 31 together.

Moreover, a dicing can be carried out by a method that is known as a so-called stealth dicing method. For the stealth dicing method, only the inside of a wafer is focused on to irradiate a laser, a focus part is degenerated, and the locus is broken by a stress for a chip separation. Consequently, the contact layer 31 cannot be cut simultaneously. As a result, this method is effective in particular.

For the stealth dicing method, in the semiconductor wafer, a brittle part is formed along a line to be cut that lays out each circuit of the semiconductor wafer. In this state, the chip groups are connected to each other via the brittle part, and maintain a wafer shape as a whole. The brittle part is formed by focusing on the inside of the semiconductor wafer to irradiate a laser beam along a line to be cut. By irradiating a laser beam, the inside of the wafer is locally heated and degenerated due to a variation of a crystal structure. The degenerated part is put under the excess stress state as compared with peripheral parts, and is potentially weak. Consequently, in the case in which a stress is loaded to the semiconductor wafer, a crack is grown in a vertical direction of the wafer from the brittle part as a starting point, and the wafer can be segmented into chips . As a stress, a mechanical vibration or an ultrasonic wave can be utilized, thereby segmenting the wafer on the fixing jig.

The details of the stealth dicing method are described in “Electronic Materials, September 2002, pages 17 to 21” and Japanese Patent Application Laid-Open Publication No. 2003-88982.

In the case in which a wafer bonded to a dicing sheet is segmented into chips by the stealth dicing method as described above, the wafer can be segmented into chips simultaneously with an expand. A tensile force for stretching the dicing sheet during the expand is transmitted to the wafer fixed on the dicing sheet. In the case in which a brittle part has been formed in the wafer in this case, the brittle part cannot resist the tensile force, and a subsidiary fracture occurs in the brittle part. As a result, a crack is generated in a vertical direction of the wafer from the brittle part as a starting point, and the wafer can be segmented into chips. The chips formed as described above are transferred from the dicing sheet to the contact layer of the fixing jig, whereby the chips can be arranged on the fixing jig.

Moreover, a so-called dicing before grinding can be applied. More specifically, a groove having a cut depth smaller than a thickness of the wafer is formed from the surface of the wafer on which a semiconductor circuit has been formed, and a surface protection sheet is adhered to the circuit face. The rear face of the semiconductor wafer is then ground to reduce the thickness of the wafer, and chips 13 are separated from each other finally. A grinding surface is made contact with the contact layer 31, and surface protection sheet is removed. Consequently, a state in which a plurality of chips 13 is arranged in a wafer shape on the contact layer 31 can be achieved.

### <Pickup Apparatus>

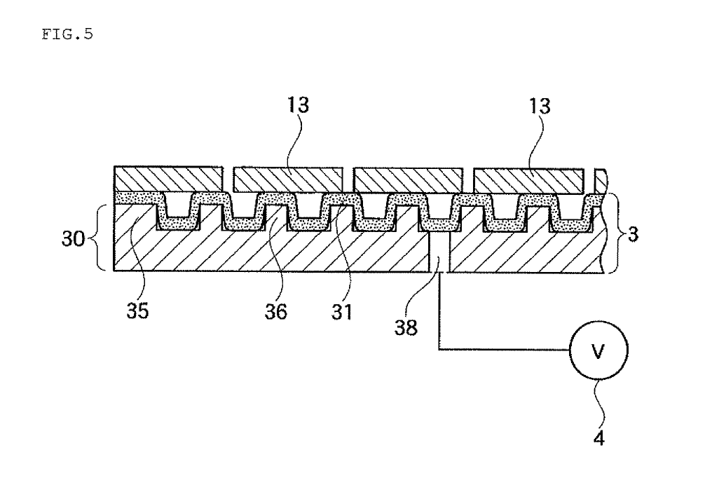

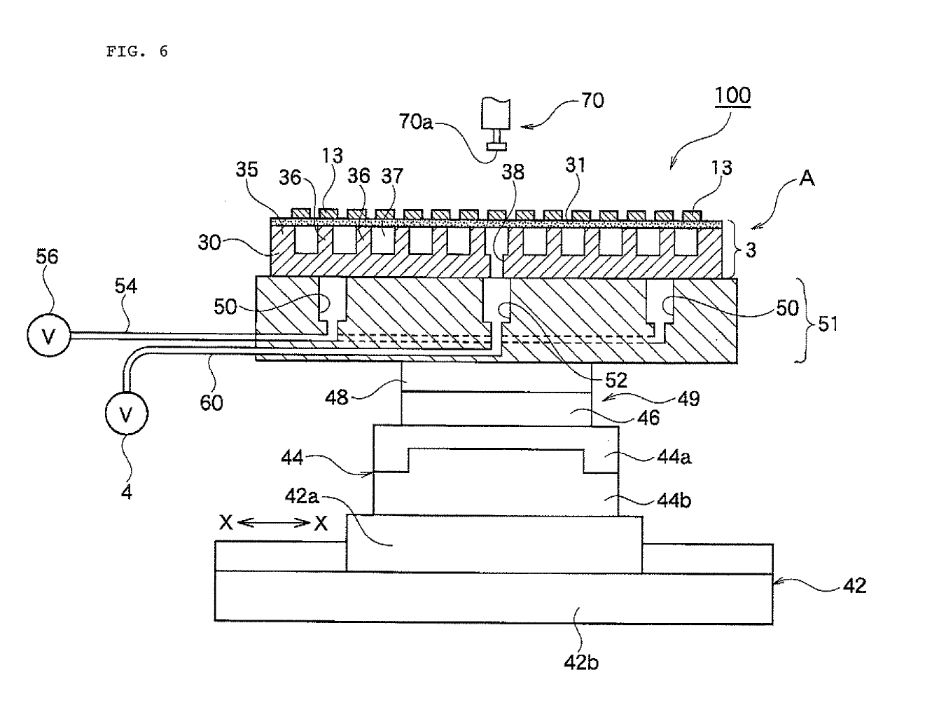

FIG. 6 is a view showing a pickup apparatus 100 in accordance with an embodiment of the present invention. FIGS. 4 and 5 are views schematically showing a pickup method using the pickup apparatus 100.

A table 51 for mounting the fixing jig 3 on the upper surface thereof is disposed in the pickup apparatus 100 in accordance with an embodiment of the present invention. A plurality of suction parts 50 for suctioning and fixing the jig base 30 that configures the lower part of the fixing jig 3 are formed in the table 51. In addition, a suction part 52 for suctioning the section space 37 via the through hole 38 of the fixing jig 3 is formed in the central part of the table 51. The plurality of suction parts 50 are formed outside the suction part 52. The plurality suction parts 50 are communicated with each other inside the table 51 and are also connected to a vacuum apparatus 56 via a piping path 54. On the other hand, the suction part 52 is formed at the position corresponding to the through hole 38 of the fixing jig 3. The suction part 52 is connected to another vacuum apparatus 4 via a piping path 60. Each of the vacuum apparatuses can be controlled independently.

For the pickup apparatus 100 configured as described above, the fixing jig 3 disposed on the table 51 can be fixed unmovably by operating the vacuum apparatus 56. On the other hand, by operating the vacuum apparatus 4, the contact layer 31 of the fixing jig 3 is deformed in a concave-convex shape, and a chip 13 on the contact layer 31 is shifted to a state that the chip 13 can be picked up.

For the pickup apparatus 100 in accordance with an embodiment of the present invention, the table 51 can be moved in an X direction, a Y direction, and a rotating direction. The pickup apparatus 100 is provided with a first table 42 movable in an X direction, a second table 44 movable in a Y direction perpendicular to the X direction (in a direction perpendicular to the paper face of FIG. 6) on the first table 42, and a rotating apparatus 49 in the order from the base part of the apparatus frame. For the first table 42, an operating base 42a on the upper side is moved in an X direction to a lower part 42b. For the second table 44, an operating base 44a on the upper side is moved in a Y direction to a lower part 44b. Moreover, a rotating base 46 provided with a motor is disposed on the second table 44. An upper turntable 48 can be rotated at any angle in a horizontal direction by the movement of the rotating base 46. The table 51 provided with the suction parts 50 and 52 is set on the turntable 48.

For the pickup apparatus 100 in accordance with an embodiment of the present invention, a suction collet 70 is disposed above the table 51. The suction collet 70 is provided with a suction part 70a disposed under the collet, and is communicated with a vacuum apparatus (not shown). The lower face of the suction part 70a can suction and hold the chip 13. Moreover, an arm portion of the suction collet 70 can be moved in a vertical direction and in a horizontal direction. Consequently, the suction part 70a can move down toward the chip 13 to suction the chip 13, and can pick up the chip 13 from the fixing jig 3. Moreover, the arm portion can move upward and then in a horizontal direction, whereby the suction collet 70 can transfer the chip 13 to a desired location.

A chip recovery unit or a chip bond unit (not shown) is disposed on the side of the pickup apparatus 100, and receives the chip 13 that is transferred by the suction collet 70 to carry out the prescribed processing.

A pickup method of the chip 13 using the pickup apparatus 100 in accordance with an embodiment of the present invention will be described below.

By the above described means, a semiconductor wafer is segmented into chip pieces to arrange the chips 13 on the surface of the contact layer 31 of the fixing jig 3. The fixing jig 3 to which the chips 13 contact is disposed on the table 51 of the pickup apparatus 100 in such a manner that the through hole 38 of the fixing jig 3 and the suction part 52 of the table 51 are corresponded to each other. The vacuum apparatus 56 is operated to apply a negative pressure to a plurality of suction parts 50, whereby the fixing jig 3 can be held unmovably to the table 51. The vacuum apparatus 4 is then operated to suction the section space 37 of the fixing jig 3, thereby deforming the contact layer 31 in a concave-convex shape. By the above operation, the chips 13 can contact to the contact layer 31 by a point contact, and can be picked up without the pushing up using a fine needle.

Subsequently, the arrangement of the chips 13 is observed by a camera or the like (not shown). The first table 42, the second table 44, and the rotating apparatus 49 are then operated to move the table 51 to a prescribed position in such a manner that a position of a chip to be picked up is corresponded to the receiving point of the suction collet 70. In the case in which it is confirmed that the X direction, the Y direction, and an angle of the targeted chip are corresponded to the suction collet 70, the suction collet 70 is moved downward. When the suction collet 70 comes very close to the chip 13 in the state in which the suction collet 70 is not in touch with the chip 13, a negative pressure is applied to the suction part 70a to pick up the chip 13 from the contact layer 37 of the fixing jig 3. The chip 13 that has been picked up is transferred to a chip recovery unit or a chip bond unit (not shown) by the suction collet 70, and a prescribed processing is carried out in the next step.

As described above, the pickup apparatus 100 in accordance with an embodiment of the present invention does not require the pushing up of a chip using a fine needle. Consequently, the chip 13 is not damaged, and a high quality chip can be supplied to the next step.

1. A method for picking up chip from a fixing jig to which the chip is fixed,
the fixing jig comprising a jig base provided with a plurality of protrusions on one side thereof and a sidewall having a height almost equivalent to that of the protrusion at the outer circumference section of the one side, and an contact layer that is laminated on the surface of the jig base having the protrusions and that is bonded on the upper surface of the sidewall,
the jig base comprising a section space that is formed on the surface of the jig base having the protrusions by the contact layer, the protrusions, and the sidewall, and at least one through hole penetrating from the outside to the section space,
wherein the chip pickup method comprises the steps of:
fixing a chip in a state in which the chip is fixed to the surface of the contact layer of the fixing jig;
deforming the contact layer by suctioning an air in the section space through the through hole; and
picking up the chip completely from the contact layer by suctioning the chip from the upper surface side of the chip by means of a suction collet.

2. The chip pickup method as defined in claim 1, wherein the chip is a semiconductor chip that is obtained by segmenting a semiconductor wafer into chip pieces.

3. The chip pickup method as defined in claim 2, wherein the semiconductor chips are obtained by segmenting a semiconductor wafer into chip pieces through dicing on a dicing sheet, and
wherein the semiconductor chips are arranged on the surface of the contact layer of the fixing jig by contacting an exposed face of the semiconductor chips to the contact layer of the fixing jig, and removing the dicing sheet.

4. The chip pickup method as defined in claim 2, wherein the semiconductor chips are obtained by half-cutting a circuit face of the semiconductor wafer, protecting the circuit face with a protection sheet, and grinding the rear face of the semiconductor wafer up to a half-cut groove whereby the semiconductor wafer is segmented into chip pieces, and
wherein the semiconductor chips are arranged on the surface of the contact layer of the fixing jig by contacting an exposed face of the semiconductor chips to the contact layer of the fixing jig, and removing the protection sheet.

5. The chip pickup method as defined in claim 2, wherein a semiconductor wafer is irradiated with a laser beam to form a brittle part in the semiconductor wafer;
the position of the laser beam incident on the wafer surface is moved to create the brittle parts in a desired outline; and
a shock is applied to the semiconductor wafer to break the brittle parts and thereby the wafer is segmented into pieces; and
wherein the semiconductor wafer is contacted to the contact layer of the fixing jig before irradiated with the laser beam.

6. A chip pickup apparatus that is used in the pickup method as defined in claim 1, comprising:
a table for fixing the fixing jig; and
a suction collet for suctioning and holding the chip,
wherein the table is provided with a suction part for fixing the fixing jig body, and a suction part for suctioning the section space connected to a through hole of the fixing jig, in which the suction parts are openings and capable of suctioning independently.

7. The chip pickup apparatus as defined in claim 6, wherein the table can move in an X direction, a Y direction, and a rotating direction, and can control the position in such a manner that a targeted chip and the suction collet can be aligned with each other.

8. A chip pickup apparatus that is used in the pickup method as defined in claim 2, comprising:
a table for fixing the fixing jig; and
a suction collet for suctioning and holding the chip,
wherein the table is provided with a suction part for fixing the fixing jig body, and a suction part for suctioning the section space connected to a through hole of the fixing jig, in which the suction parts are openings and capable of suctioning independently.

9. A chip pickup apparatus that is used in the pickup method as defined in claim 3, comprising:
a table for fixing the fixing jig; and
a suction collet for suctioning and holding the chip,
wherein the table is provided with a suction part for fixing the fixing jig body, and a suction part for suctioning the section space connected to a through hole of the fixing jig, in which the suction parts are openings and capable of suctioning independently.

10. A chip pickup apparatus that is used in the pickup method as defined in claim 4, comprising:
a table for fixing the fixing jig; and
a suction collet for suctioning and holding the chip,
wherein the table is provided with a suction part for fixing the fixing jig body, and a suction part for suctioning the section space connected to a through hole of the fixing jig, in which the suction parts are openings and capable of suctioning independently.
